(19) United States
(12) Patent Application Publication
(10) Pub. No.: US 2024/0396319 A1
(43) Pub. Date: Nov. 28, 2024

(54) LOCATING AN ARC

(71) Applicant: Siemens Aktiengesellschaft, München (DE)

(72) Inventors: Ricardo Herrmann, Dresden (DE); Peter Schegner, Dresden (DE); Karsten Wenzlaff, Dresden (DE)

(21) Appl. No.: 18/712,347

(22) PCT Filed: Oct. 31, 2022
(86) PCT No.: PCT/EP2022/080361

§ 371 Date: May 22, 2024

(30) Foreign Application Priority Data
Nov. 22, 2021 (DE) 10 2021 213 109.3

(51) Int. Cl. H02H 1/00; G01R 31/327; H02H 3/04

(52) U.S. Cl. CPC H02H 1/0023; G01R 31/3274; H02H 3/042

(57) ABSTRACT

A method locates an arc in a switchgear apparatus. The switchgear apparatus is subdivided into two or more detection zones, each detection zone is assigned at least one radiation sensor, the detection angle range of which covers the assigned detection zone. The radiation sensors sense the intensity of the radiation arriving from the associated detection angle range during the burning of the arc. On the basis of the sensed radiation intensities and the assignment between the radiation sensors and the detection zones, the detection zone in which the arc is located is determined.

The present invention relates to a method for locating an arc in a switchgear assembly and a device for carrying out the method.

In low-voltage grids, short circuits are for the most part connected with parallel arc faults that occur. Particularly in powerful distribution and switchgear assemblies, these may, in the case of insufficiently fast shutdown, lead to devastating destruction of equipment, assembly parts or complete switchgear assemblies. In order to avoid longer lasting and large-area failure of the power supply and reduce personal injuries, it is necessary to detect and to extinguish high-current parallel arc faults of this type in a few milliseconds.

Explicit arc fault detection systems are used for detecting arc faults. The conventional arc fault detection systems that are available on the market consist of a plurality of components (multicomponent systems) which have to be installed individually at the installation location. Thus, optical waveguides are for example installed in the areas of the assembly that are to be protected. The optical waveguides detect the light emission generated by an arc and forward the optical signal to a centrally installed detection unit. On the basis of the evaluation of the optical signal and possibly further release conditions, such as e.g. overcurrent, this provides a trip signal for a short-circuiter, which is used for the most part for extinguishing the arc. When activated, the short-circuiters can generate a short circuit, e.g. by firing an internally installed explosive charge. Therefore, no more arc voltage can build up at the arc and the arc is extinguished. An arc fault detection system is described e.g. in WO 2017/050764 A1 (Siemens AG) Mar. 30, 2017.

These systems indirectly combine the arc fault location and the arc fault detection when an evaluation of the responding sensor is carried out. However, the accuracy of the location is limited only to the detection zone of the sensor. An accurate position of the arc firing point cannot be determined using the existing systems.

The object of the present invention is therefore to provide an improved arc location.

This object is achieved according to the invention by a method as claimed in claim 1 and a device as claimed in claim 7.

The method according to the invention is used for locating an arc in a switchgear assembly. Location means the determination of a location or a region or a zone at which an arc is burning in the switchgear assembly. A switchgear assembly is an assembly for switching and distributing electrical energy. The switching and distribution takes place by connecting and interrupting one or more transmission lines of electrical energy; to this end, the switchgear assembly can be connected by a single- or multiphase electrical input line to an electrical energy source, e.g. an electrical grid, and by one or more single- or multiphase electrical output lines to one or more electrical loads, e.g. an electric motor or an electric light source. The switchgear assembly has at least one single- or multiphase connecting line which electrically conductively connects the electrical input line and the one or more electrical output lines to one another. The switchgear assembly additionally has at least one switching device, e.g. a relay, or a contactor for interrupting the at least one connecting line. To this end, the switching device can, by means of a mechanically operating switch, create a galvanic isolation and/or, by means of an electronically operating semiconductor switch, create a high-resistance isolation of the connecting line.

The switchgear assembly-more precisely: a spatial volume of a switchgear assembly which is to be monitored for an arc, in which electrical lines run and the danger of arc creation exists, e.g. an interior of the switchgear assembly—is divided into two or more detection zones in that the spatial volume to be monitored is conceptually divided into two or more spatial regions. The aim of the invention is to localize the location of an arc in one of these detection zones. Therefore, the location of an arc can take place more accurately, the more detection zones are defined. In order to ensure a clear location of the arc, it is advantageous if the detection zones do not overlap.

Each detection zone is assigned at least one radiation sensor, the detection angular range of which covers the assigned detection zone. A radiation sensor is characterized by a detection angular range, i.e. a solid angle, wherein the radiation sensor can exclusively detect that radiation which lies above a predetermined energetic detection threshold and which makes it into the sensor from this detection angular range. A radiation sensor therefore has directed radiation detection, wherein the radiation sensor is able to detect the incoming radiation from the assigned detection zone.

During the burning of an arc in the switchgear assembly, the radiation sensors detect the incoming radiation intensity from their respective detection angular range. The radiation sensors therefore offer the possibility of measuring the intensity of the incoming radiation, so that at least one comparison between the radiation sensors can take place as to at which radiation sensor the highest intensity was present.

On the basis of the detected radiation intensities and the assignment between the radiation sensors and the detection zones, the detection zone in which the arc is located is determined. The detected radiation intensities are assigned to the respective detection angular ranges; the detection angular ranges are assigned to the respective radiation sensors; and the radiation sensors are assigned to the respective detection zones. Therefore, an assignment between the radiation intensities and the detection zones can take place and it is possible to determine the detection zone in which the arc is burning.

The device according to the invention is used for locating an arc in a switchgear assembly. The device has two or more radiation sensors, the detection angular range of which in each case covers an assigned detection zone, into which the switchgear assembly is divided. In this case, the radiation sensors are configured, during the burning of the arc, to detect the radiation intensity that is incoming from the respective detection angular range. The device additionally has an arithmetic logic unit which is connected to the radiation sensors. The arithmetic logic unit can be an arithmetic logic unit which is integrated together with the radiation sensors into a housing. The arithmetic logic unit can be a controller or a processor, e.g. a microcontroller that is arranged on a printed circuit board. The arithmetic logic unit can however also be an arithmetic logic unit which is arranged externally from the radiation sensors and which is connected to the radiation sensors via externally running data connections (wired or wireless). The arithmetic logic unit is configured to determine the detection zone in which the arc is located on the basis of the detected radiation intensities and the assignment between the radiation sensors or the corresponding detection angular ranges and the detection zones. To this end, the arithmetic logic unit can execute a correspondingly configured computer program.

The invention is based on the discovery that radiation sensors having directed detection enable the location of an arc event, e.g. ignition of the arc. With the aid of directed radiation sensors, the position of a radiation source can be confined. In this case, it is assumed that the radiation reaches the sensor on the direct path and no reflection can distort the direction. The direction decision is undertaken by means of the comparison of the radiation intensities which were detected by variously oriented radiation sensors. Stated in simple terms, the radiation sensor having the highest intensity indicates the direction to the radiation source and therefore to the arc; in other words: the arc is located in the region of a switchgear assembly from which the highest radiation intensity arrives. In this case, the feature of an arc to output electromagnetic radiation intensively, which starts after its ignition, is used to locate the arc.

Using the invention, parallel high-current arc faults can be located in switchgear and distribution assemblies by a locating system that does not have to fulfill any time requirements with regard to an arc fault detection system. The locating system consists of a plurality of directed radiation sensors that evaluate typical non-electrical signals for an arc and determine the position of the arc by means of the evaluation of intensities.

Using the locating method for arcs, it is possible to offer a locating system which, compared to conventionally available optical detection systems, can locate an arc in a switchgear assembly to an accuracy of a few centimeters. As this locating method does not explicitly belong to the protection system, no particular protection-relevant requirements would have to be considered here, which allows a cost-saving embodiment.

Due to the use of a locating system in a switchgear assembly, the following advantages result:
Using the locating system, a high level of accuracy of the localization of an arc can be achieved: An arc can be located in a switchgear assembly with an accuracy of a few centimeters.
The locating system leads to lower installation costs: Costly installation of optical waveguides in the switchgear assembly under protection-related requirements, which is necessary for a conventional locating system, is not required.
The invention differentiates between detection and location. A detection system, i.e. a central arc fault detection system based on current and voltage measurement forms the protection function in the switchgear assembly. The locating system according to the invention locates an arc self-sufficiently, i.e. independently of the detection system. It is possible only to undertake an evaluation of the results of the arc location in the event that an arc has been detected by the detection system. As the detection of the arcs is therefore not based on the locating system, the locating system cannot cause faulty tripping of arc detection.

Advantageous embodiments and developments of the invention are specified in the dependent claims. In this case, the method according to the invention can also be developed according to the dependent device claims and vice versa.

According to an advantageous embodiment of the invention, the radiation intensity in the UV, VIS or IR range is measured. Thus, the spectral ranges, in which the spectral energy density of the arc emission is highest, are covered.

According to an advantageous embodiment of the invention, the electromagnetic radiation is measured in the UV range. This has the particular advantage that the radiation signal emitted by the arc in the UV wavelength range is overlaid less by other radiation types, e.g. IR heat radiation from all surrounding bodies and the visible light which reaches the interior of the switchgear assembly e.g. by means of ventilation slots (ambient light), than in a different spectral range. The UV light arriving at the at least one radiation sensor generally originates to the greatest extent from the arc, as an arc is a strong UV emitter owing to its high temperature.

According to an advantageous embodiment of the invention, precisely one radiation sensor is assigned to each detection zone in a one-to-one manner, the detection angular range of which radiation sensor corresponds to the assigned detection zone. One-to-one means that precisely one radiation sensor is assigned to each detection zone and precisely one detection zone is assigned to each radiation sensor. The arc is then localized in the detection zone for which the assigned radiation sensor has detected the highest radiation intensity.

According to an advantageous embodiment of the invention, the highest radiation intensity is defined as the absolute maximum radiation intensity in the entire time curve of all radiation sensors. Therefore, the absolute radiation maximum is determined here.

According to an advantageous embodiment of the invention, the highest radiation intensity is defined as the highest radiation intensity of all radiation sensors averaged over the entire time curve. The following equation is one possibility for how the averaged (mean) radiation intensity Ii,mean of a radiation sensor i can be calculated:

$${I}_{i , m e a n} = \frac{1}{{t}_{LB , end} - {t}_{r z}} {\int }_{{t}_{rz}}^{{t}_{LB , end}} {I}_{i} ( t ) d t$$

In this case, the time-variable radiation intensity Ii(t) over the time period from the reference time trz to tLB, end (the end of the emission of the arc LB) received by the radiation sensor i is integrated and divided by the time period tLB, end-trz. In this case, the reference time trz can be the time at which the emission of the arc LB begins, particularly the time at which the emission of the arc LB exceeds a predetermined threshold value for the first time.

According to an advantageous embodiment of the invention, the switchgear assembly is in each case divided along two or more linearly independent axes into two or more detection zones. In this manner, a geometrically distinct division is achieved, which allows an uncomplicated assignment of the detection zones to different radiation sensors and simple coverage by the detection angular ranges of the radiation sensors.

According to an advantageous embodiment of the invention, the switchgear assembly is a low-voltage switchgear assembly. Low voltage means voltages up to 1000 volts AC or 1500 volts DC. Low voltage is more specifically understood to mean, in particular, voltages greater than extra-low voltage, with values of 50 volts AC or 120 volts DC.

In addition, a computer program product is proposed, which can be loaded directly into the internal memory of a digital arithmetic logic unit, particularly a processor of the sensor arrangement, and comprises software code sections, using which the step “determination of the detection zone in which the arc is located on the basis of the detected radiation intensities and the assignment between the radiation sensors and the detection zones” of the method described herein is executed when the product runs on the arithmetic logic unit. The computer program product can be stored on a data carrier, such as e.g. a USB memory stick, a DVD or a CD-ROM, a flash memory, EEPROM or an SD card. The computer program product can also be present in the form of a signal that can be loaded via a wired or wireless network.

The method is realized for automatic execution, preferably in the form of a computer program. The invention is therefore on the one hand also a computer program having program code instructions that can be executed by a computer and on the other hand a storage medium having a computer program of this type, that is to say a computer program product having program code means and finally also a switchgear assembly, in the memory of which such a computer program is or can be loaded as means for carrying out the method and its embodiments.

When method steps or sequences of method steps are described in the following, this relates to actions that take place owing to the computer program or under the control of the computer program insofar as it is not explicitly noted that individual actions are caused by a user of the computer program. At least, each use of the term “automatic” means that the relevant action takes place owing to the computer program or under the control of the computer program.

Instead of a computer program having individual program code instructions, the implementation of the method described here and in the following can also take place in the form of firmware. It is clear to a person skilled in the art that instead of an implementation of a method in software, an implementation in firmware or in firm- and software or in firm- and hardware is also always possible.

Therefore, it should be true for the description presented here that the term software or the term computer program also includes other implementation possibilities, namely particularly an implementation in firmware or in firm- and software or in firm- and hardware.

The above-described properties, features and advantages of this invention and the manner in which these are achieved become clearer and more clearly understandable by means of the following description of the exemplary embodiments which are explained in more detail with reference to the drawings. In the drawing, schematically and not to scale in each case,

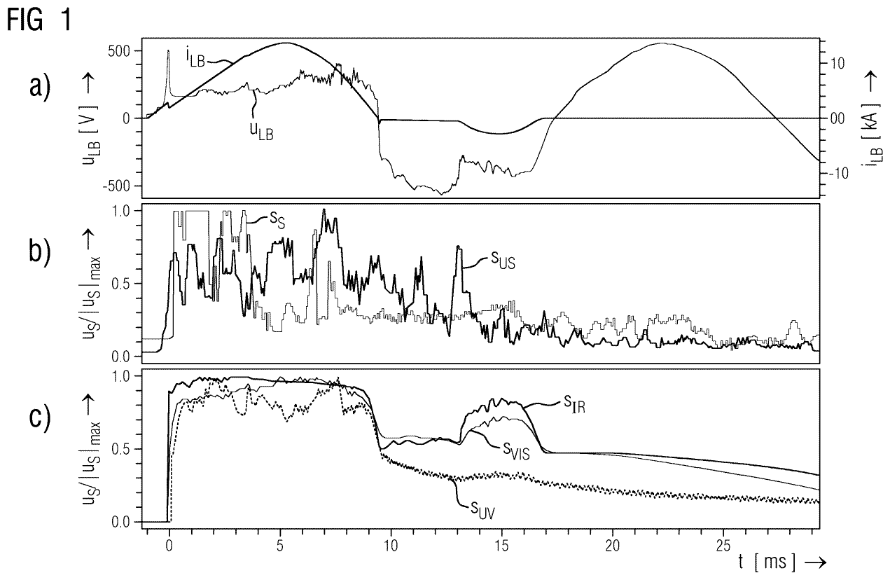

FIG. 1 shows the voltage and current values and the sound and radiation emission of an arc;

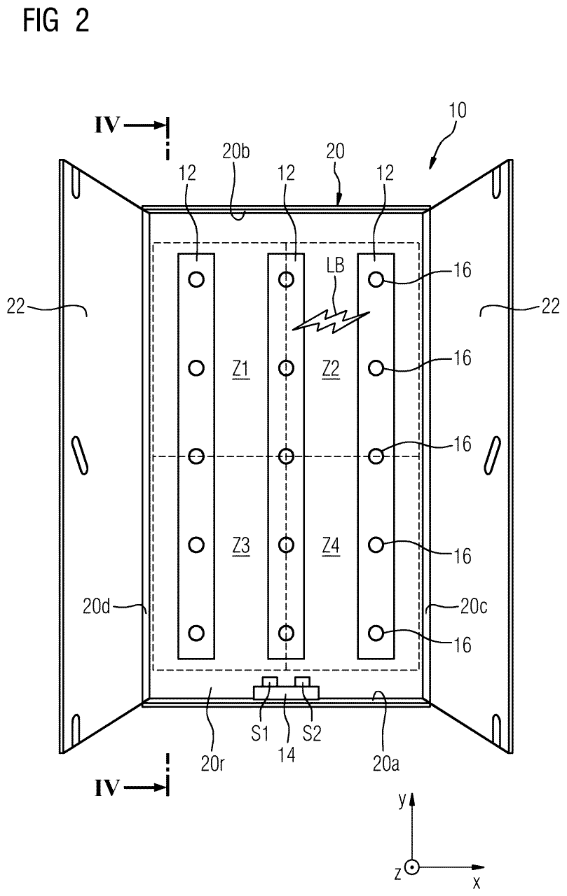

FIG. 2 shows a switchgear assembly in a front view;

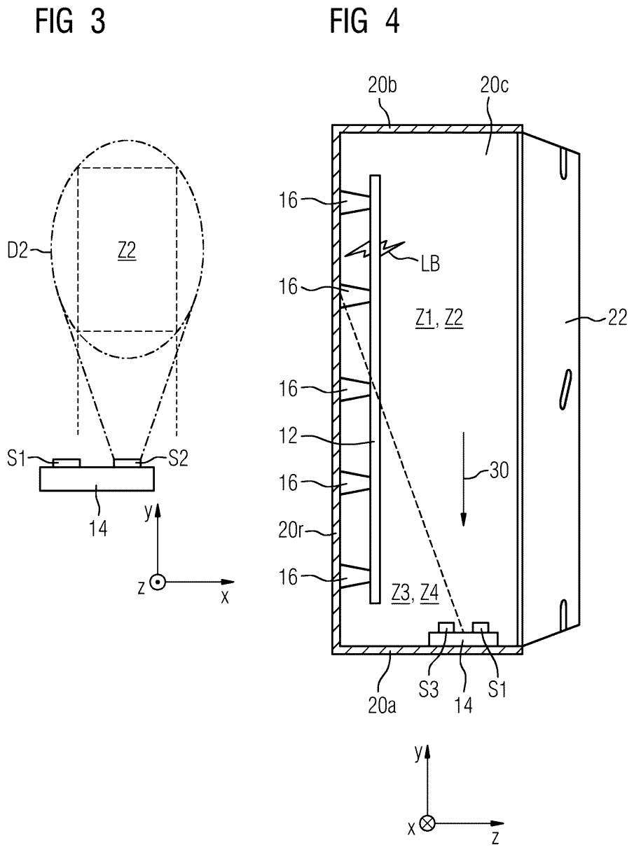

FIG. 3 shows a detection angular range of a radiation sensor;

FIG. 4 shows a section of the switchgear assembly of FIG. 2;

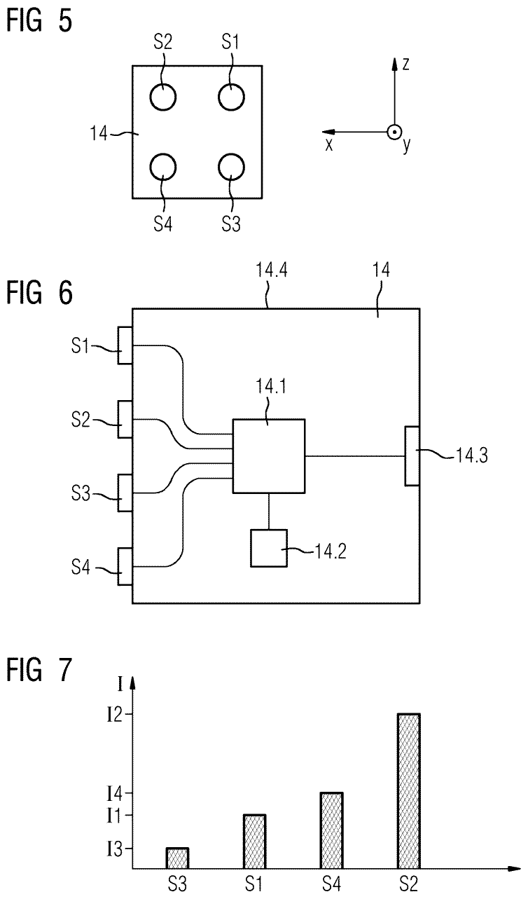

FIG. 5 shows a view of a sensor arrangement;

FIG. 6 shows a design of the sensor arrangement;

FIG. 7 shows radiation intensities which are measured during the burning of an arc by various radiation sensors of the sensor arrangement;

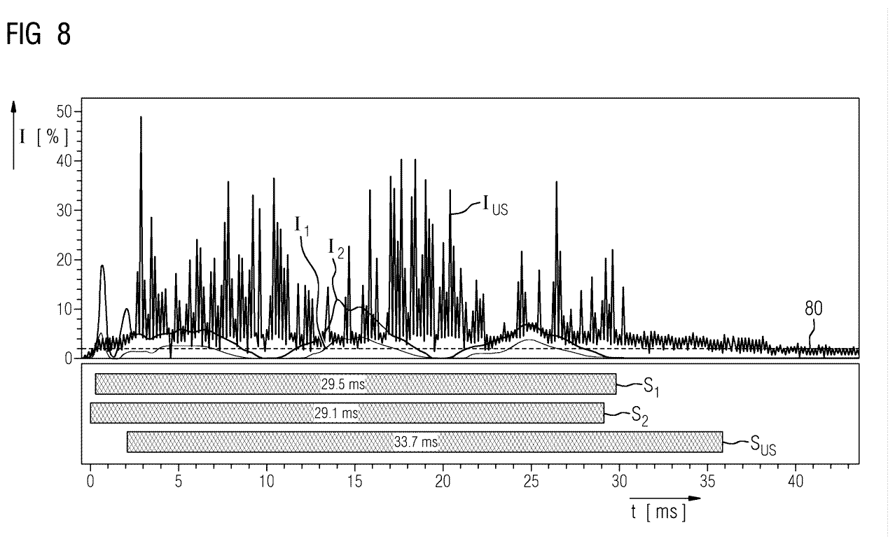

FIG. 8 shows the time curve of ultrasound and UV measurement variables which are detected during the ignition of an arc;

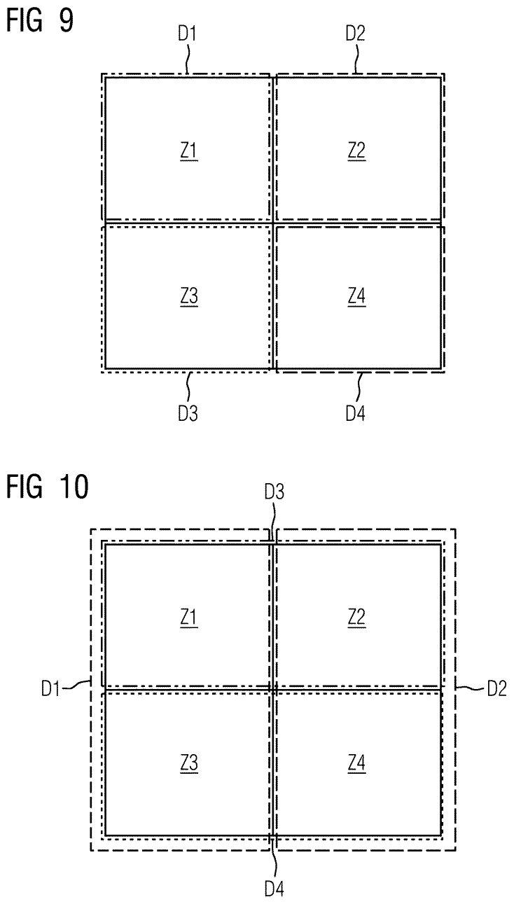

FIG. 9 shows a first assignment between detection zones and detection angular ranges; and

FIG. 10 shows a different assignment between detection zones and detection angular ranges.

FIG. 1 shows the time curve of various measurement variables that were detected during the ignition of an arc at time t=0 ms and up to approx. 29 ms after the ignition of the arc. In a short time, an arc reaches temperatures in the region of a few 10 000 K. Therefore, an arc has an intensive electromagnetic emission with a radiation maximum in the UV spectral range. In addition, due to the high temperature in the arc, the air surrounding the arc expands rapidly, which can be perceived as a sound emission of the arc.

Graph a shows the voltage uLB across and the current iLB through the arc.

Graph b shows the modulation of a sound sensor SS that receives in the range of human hearing and an ultrasound sensor SUS, which sensors detect the sound generated by the arc; in this case, the modulation is calculated as a quotient of the measured voltage values us of the sound sensors SS, SUS and the absolute value of the maximum voltage value |uS|max.

Graph c shows the modulation of an IR sensor SIR, a VIS sensor SVIS and a UV sensor SUV which detect the electromagnetic radiation generated by the arc; in this case, the modulation is calculated as a quotient of the measured voltage values uS of the radiation sensors SIR, SVIS, SUV and the absolute value of the maximum voltage value |uS|max.

This feature of an arc to emit electromagnetic radiation and sound waves intensively, which starts after its ignition, can be used to locate the arc.

FIG. 2 shows a switchgear assembly 10 in a front view. The switchgear assembly 10 has a box-like housing 20 having a rear wall 20r in the x-y plane and four side walls 20a, 20b, 20c, 20d which are placed at the edges of the rear wall 20r. The switchgear assembly 20 additionally has a door with two door leaves 22, using which the housing 20 can be closed during operation. A three-phase electrical connecting line is installed in the housing 20, which is configured as three electrically conductive busbars 12 which are in each case fixed on the rear wall 20r of the housing 20 with the aid of carrier elements 16. The busbars 12 are at different electrical potentials during the operation of the switchgear assembly 10; therefore, in the event of a fault, an arc LB can occur between two busbars 12.

The switchgear assembly 10 is divided into four detection zones Z1, Z2, Z3, Z4, which are displayed in FIG. 2 by dashed lines which indicate the boundaries of the detection zones Z1, Z2, Z3, Z4. A sensor arrangement 14 is fastened at the lower side wall 20a of the housing 20, which sensor arrangement has four radiation sensors S1, S2, S3, S4 which are arranged in a square. Each detection zone Z1, Z2, 3, Z4 is assigned in a one-to-one manner to precisely one of the radiation sensors S1, S2, S3, S4 and vice versa. In this case, the detection angular range D1, D2, D3, D4 of each radiation sensor S1, S2, S3, S4 covers the detection zone Z1, Z2, Z3, Z4 which is assigned to it: a radiation emission occurring in one detection zone Z1, Z2, Z3, Z4 is detected by the radiation sensor S1, S2, S3, S4 assigned to the detection zone Z1, Z2, Z3, Z4.

FIG. 3 shows as an example that the detection angular range D2 of the second radiation sensor S2 covers the second detection zone Z2 which is assigned to the second radiation sensor S2: therefore, it is ensured that a radiation emission occurring in the second detection zone 22 can be detected by the second radiation sensor S2.

FIG. 4 shows a section of the switchgear assembly 10 along the sectional plane IV-IV that is drawn in FIG. 2. The sensor arrangement 14 that is fastened on the lower side wall 20a has three radiation sensors S1, S2 which cover the detection zones Z1, 22 which are further removed from the sensor arrangement 14 and two radiation sensors S3, S4 which cover the detection zones Z3, 24 which are located closer to the sensor arrangement 14. In the section of FIG. 4, only the two radiation sensors S1 and S3 are visible, which cover the two other radiation sensors S2 and S4.

FIG. 5 shows a view of the sensor arrangement 14 in the viewing direction 30 that is drawn in FIG. 4. The four radiation sensors S1, S2, S3, S4 are arranged in a square. Each of the radiation sensors S1, S2, S3, S4 detects the radiation emission in one of the four detection zones Z1, Z2, Z3, Z4. In this case, the two radiation sensors S1, S2 that are arranged at higher z coordinates are assigned to the detection zones Z1, 22 that are further removed from the sensor arrangement 14 and the two radiation sensors S3, S4 that are arranged at lower z coordinates are assigned to the detection zones Z3, 24 that are located closer to the sensor arrangement 14. For the sensor arrangement 14, radiation sensors S1, S2, S3, S4, which have an adjustable detection angular range D1, D2, D3, D4, are preferably used; in this manner, the detection angular range D1, D2, D3, D4 of a radiation sensor S1, S2, S3, S4 can be adapted to the solid angle under which the radiation sensor “sees” the detection zone assigned to it.

FIG. 6 illustrates the design of a sensor arrangement 14. Apart from a housing 14.4 and the radiation sensor S1, S2, S3, S4 that is arranged on the front side of the housing 14.4, the sensor arrangement 14 has a processor 14.1, a data memory 14.2 and an interface 14.3. The radiation sensors S1, S2, S3, S4 are connected via data connections to the processor 14.1; measured values of the radiation sensors S1, S2, S3, S4 can be transmitted from the radiation sensors S1, S2, S3, S4 to the processor 14.1 via the data lines. The processor 14.1 is configured to process the received measured values of the radiation sensor S1, S2, S3, S4 further. In this case, the processor 14.1 can access a data memory 14.2 via a data connection. Measured values or analysis results that are obtained therefrom can be stored in the data memory 14.2. A computer program, e.g. an analysis program for evaluating and analyzing sensor measured values, can be stored in the data memory 14.2, which computer program the processor 14.1 can load into its main memory and execute. The analysis program is designed to determine the detection zone in which the arc is located on the basis of the detected radiation intensities and the assignment between the radiation sensors or the corresponding detection angular ranges and the detection zones. Via the interface 14.3, to which the processor 14.1 is connected via a data connection, the processor 14.1 can transmit data to an external data processing installation, e.g. a laptop of a technician, or an external output device, e.g. a smartphone of a user, or receive data, e.g. commands, computer programs or updates of computer programs. In this case, the interface 14.3 can be designed as an end point of a radio connection or a wired transmission connection.

FIG. 7 shows, as a bar graph, the radiation intensities I1, I2, I3, I3 that are measured by the radiation sensors S1, S2, S3, S4 during burning of the arc LB that is drawn in FIGS. 2 and 4. The second radiation sensor S2 measures the highest radiation intensity I2. The fourth radiation sensor S4 measures the second highest radiation intensity I4. The first radiation sensor S1 measures the third highest radiation intensity I1. The third radiation sensor S3 detects the lowest radiation intensity I3. From this graph, it is therefore possible to read off that the arc LB is burning in the detection zone Z2 assigned to the second radiation sensor S2. The distribution of the radiation intensities to the radiation sensors S1, S2, S3, S4 therefore allows localization of the arc LB in one of the detection zones Z1, Z2, Z3, Z4 of the switchgear assembly 10.

FIG. 8 shows, by way of example, an evaluation of the time signals for the direction decision, i.e. for deciding whether an arc is burning in a first detection zone Z1, to which a first radiation sensor S1 is assigned, or in a second detection zone Z2, to which a second radiation sensor S2 is assigned. After the ignition of the arc, UV signals reach the two radiation sensors S1 and S2 and, because of the different propagation speeds of UV radiation and ultrasound, an ultrasound signal, which is delayed by approx. 2 ms, reaches an ultrasound sensor arranged directly next to the radiation sensors.

The upper graph of FIG. 8 shows the modulation of the sensors as relative intensity signals 11, 12 of the radiation sensors S1 or S2 and as relative intensity signal IUS of the ultrasound sensor, in percent in each case, which is calculated as a quotient of the measured intensity over the maximum intensity.

The radiation sensors S1 and S2 are excited by a received UV signal as soon as the intensity of the UV signal is above the UV tripping threshold value 80 of the radiation sensors S1 and S2. The same is true for the ultrasound detection. The lower graph of FIG. 8 shows the time periods of excitation of the sensors as bars. The second radiation sensor S2 receives a stronger UV signal than the first radiation sensor S1 over the entire time period of the radiation emission from t=0 ms to t=30 ms. In addition, the UV signal received at the second radiation sensor S2 exceeds the UV tripping threshold value 80 sooner than the first radiation sensor S1. From this, it is possible to conclude that the arc is burning in the second detection zone Z2, to which the second radiation sensor S2 is assigned.

FIG. 9 shows a first assignment between detection zones and detection angular ranges. In this case, the interior of the switchgear assembly, which is to be monitored for an arc, is divided into four detection zones Z1, Z2, Z3, Z4 of equal size arranged in a square, wherein each of the detection zones Z1, Z2, Z3, Z4 is covered by a detection angular range D1, D2, D3, D4 which exclusively and precisely captures the respective detection zone Z1, Z2, Z3, Z4, as the following table 1 shows:

TABLE 1

| Detection | covered by detection |
|---|---|
| zone | angular range |
| Z1 | D1 |
| Z2 | D2 |
| Z3 | D3 |
| Z4 | D4 |

Due to this one-to-one assignment, the arc can be localized in the detection zone for which the respective radiation sensor has detected the highest radiation intensity in its assigned detection angular range.

FIG. 10 shows an alternative assignment between detection zones and detection angular ranges. In this case, the interior of the switchgear assembly which is to be monitored for an arc is divided into four detection zones Z1, Z2, Z3, Z4 of equal size arranged in a square. Each of the detection zones Z1, Z2, Z3, Z4 is in each case covered by two of the detection angular ranges D1, D2, D3, D4. On the other hand, each of the detection angular ranges D1, D2, D3, D4 covers two of the detection zones Z1, Z2, Z3, Z4, as the following table 2 shows:

TABLE 2

| Detection | covered by detection |
|---|---|
| zone | angular range |
| Z1 | D1 and D3 |
| Z2 | D2 and D3 |
| Z3 | D1 and D4 |
| Z4 | D2 and D4 |

For example, the arc may be burning in the detection zone Z1. Consequently, if the highest radiation intensity is measured in the detection angular ranges D1 and D3, therefore according to table 2 only the detection zone Z1 comes into consideration as location of the arc.

Due to this assignment, the arc can be localized in the detection zone for which the respective radiation sensors have detected the highest radiation intensities in its assigned detection angular range pair.

1-7. (canceled)

8. A method for locating an arc in a switchgear assembly, the switchgear assembly having radiation sensors and being divided into two or more detection zones, and each of the detection zones is assigned at least one of said radiation sensors, a detection angular range of the at least one radiation sensor covers an assigned detection zone of the detection zones, which comprises the steps of:
using the radiation sensors to detect an intensity of incoming radiation from a respective said detection angular range during a burning of the arc; and
determining, on a basis of detected radiation intensities and an assignment between the radiation sensors and the detection zones, a detection zone in which the arc is located.

9. The method according to claim 8, which further comprises measuring a radiation intensity in the ultraviolet (UV), visible (VIS) or infrared (IR) range.

10. The method according to claim 8, wherein:
precisely one of said radiation sensors is assigned to each of the detection zones in a one-to-one manner, the detection angular range of said one radiation sensor corresponds to an assigned said detection zone; and
the arc is localized in the detection zone for which an assigned said radiation sensor has detected a highest radiation intensity.

11. The method according to claim 10, wherein the highest radiation intensity is defined as an absolute maximum radiation intensity in an entire time curve of all the radiation sensors.

12. The method according to claim 10, wherein the highest radiation intensity is defined as the highest radiation intensity of all radiation sensors averaged over an entire time curve.

13. The method according to claim 8, wherein the switchgear assembly is in each case divided along two or more linearly independent axes into two or more said detection zones.

14. A device for locating an arc in a switchgear assembly, the device comprising:
two or more radiation sensors, a detection angular range of said radiation sensors in each case covers an assigned detection zone, into which the switchgear assembly is divided, said radiation sensors are configured, during a burning of the arc, to detect a radiation intensity that is incoming from a respective said detection angular range; and
an arithmetic logic unit connected to said radiation sensors and configured to determine the detection zone in which the arc is disposed on a basis of detected radiation intensities and an assignment between said radiation sensors and detection zones.
